(19) United States
(12) Patent Application Publication
(10) Pub. No.: US 2003/0181049 A1
(43) Pub. Date: Sep. 25, 2003

(54) Method for improving reliability of STI

(76) Inventors: Weng-Hsing Huang, Hsin-Chu City (TW); Kent Kuohua Chang, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,132

(22) Filed: Mar. 25, 2002

(51) Int. Cl. H01L 21/311

(52) U.S. Cl. 438/694

(57) ABSTRACT

An improved STI method having an ISSG film as an interface reinforcement layer is disclosed. The present invention includes the following steps of forming a trench-patterned mask layer on the top surface of a substrate exposing an unmasked trench region of the substrate. The mask layer is a pad oxide layer and a silicon nitride layer formed on the pad oxide layer. The unmasked region of the substrate is etched to form a trench on the substrate and the silicon nitride layer and the substrate of the trench are simultaneously oxidized to form an ISSG in-situ steam growth (ISSG) film. A dielectric layer is deposited that fills the trench and covers the mask layer. The dielectric layer is planarized to expose the silicon nitride layer, then the silicon nitride is stripped.

### BACKGROUND OF INVENTION

1. Field of the Invention

The present invention relates to a method for improving the reliability of a shallow trench isolation (STI) structure, and more particularly, to a seamless STI method utilizing an in-situ steam generation (ISSG) film, that functions as an interface reinforcement layer, to effectively protect STI edges from HF acid corrosion.

2. Background of the Invention

In recent years, there has been an increasing demand for semiconductor devices that have higher operating speeds and are more highly integrated and reliable. As device dimensions continue to shrink, the conventional local oxidation of silicon (LOCOS) technology used in VLSI/ULSI front-end processes has become no longer satisfactory to meet deep sub-micron design rules. Bird's beak effects render the LOCOS technology not suitable for current high density IC manufacturing. A new isolation process known as shallow trench isolation (STI) instead of conventional LOCOS method has become more popular and rapidly developed by virtue of its powerful packing ability. However, with great advances in the field of the defect detection engineering, random bit failures are found in some currently employed STI isolation methods. These random bit failures, lead to an increase in leakage current and worsen STI isolation decay.

Please refer to FIG. 1 to FIG. 7 of schematic diagrams depicting an STI process according to the prior art method. First, as shown in FIG. 1, a substrate 101 is etched to form a trench region 102. The trench region 102 is formed by the following steps: 1) form a mask layer 106 above a top surface of the substrate 101 to define a location of the trench region 102, 2) thereafter perform a dry-etching process such as a reactive ion etching process to etch the substrate 101 so as to form the trench region 102. The mask layer 106 is a stacked layer composed of a pad oxide layer 103, a silicon nitride layer 104 and a dielectric anti-reflection coating (DARC) layer 105. The DARC layer 105 is made of silicon oxynitride (SiON).

As shown in FIG. 2, a thermal oxidization process is performed to form a liner 107, 200 angstroms thick, on the surface of the substrate 101 contained within the trench region 102. Typically, the thermal oxidization process is conducted in an oxygen-rich environment at a temperature of approximately 950° C. for about several minutes to form the liner 107 to retrieve the lattice damage caused by the dry-etching process when forming the trench region 102. Then, a high-density plasma chemical vapor deposition (HDPCVD) process is used to deposit an HDP oxide layer 108 that covers the mask layer 106, and fills the trench region 102.

As shown in FIG. 3, a resistor layer (a reverse HDP oxide mask) 110 functions to shield the trench region 102, and an HDP oxide layer etching process is performed to etch the HDP oxide layer 108 outside the trench region 102. The purpose of the reverse HDP oxide mask and the HDP oxide layer etching process is to avoid dishing effects in the trench region 102 caused by a subsequent chemical mechanical polishing (CMP) process. The resistor layer 110 is thereafter stripped using a conventional ashing process, as shown in FIG. 4, followed by a CMP process to planarize the HDP oxide layer 108. At the end of the CMP process, the CMP process is stopped on the surface of the silicon nitride layer 104, and a remaining thickness of the silicon nitride layer 104 is left at 1300 angstroms.

As shown in FIG. 5, a so-called STI corner rounding process is then performed. The STI corner rounding process utilizes a wet oxidation method, which is performed at a temperature of about 1075° C., to oxidize the substrate 101 of a STI corner region 114. As shown in FIG. 6, an acid solution dipping process using 50:1 (v/v) diluted HF solution is then performed at room temperature for a few minutes, to clean the substrate 101. The residual silicon oxide on the silicon nitride layer 104 is removed and simultaneously, a predetermined thickness of the HDP oxide layer 108 within the trench region 102 is etched away. A preferred removed thickness of the HDP oxide layer 108 within the trench region 102 is about several hundred angstroms. Unfortunately, the diluted HF (DHF) solution corrodes the HDP oxide layer 108 of the STI corner region 114 to form small voids, also called edge voids 116. This occurs because a surface binding force between the HDP oxide layer 108 and the silicon nitride layer 104 is not strong enough to resist acid solution corrosion so producing a phenomenon of acid penetration.

As shown in FIG. 7, heated phosphoric acid solution is used to strip the silicon nitride layer 104. Then, a 100:1 (v/v) diluted HF (DHF) solution cleans the surface of the substrate 101 again for few minutes at room temperature. The previous edge voids 116 cause the acid solution to accumulate, and corrode the HDP oxide layer 108 along the edge voids 116 to form a seam defect 118. The seam defect 118 seriously affects the isolation effect of the STI, and increases current leakage.

The prior art STI method needs to repeat the acid solution dipping process a number of times, in order to achieve the objectives of cleaning the surface and stripping the silicon oxide affected by the acid solution corrosion. Furthermore, the oxide layer forming process, also requires the diluted HF (DHF) solution to be employed many times so enhancing the acid penetration's effect. The edge voids 116 and the seam defect 118 are randomly formed, so the STI method is very difficult to improve by performing extra remedial measures. Additionally, the edge voids 116 and the seam defect 118 causes abnormality in the electrical conductivity of semiconductor components. This abnormality can be seen in a double hump variation of the Id/Vg curve.

### SUMMARY OF INVENTION

It is therefore a primary objective of the present invention to provide a shallow trench isolation method to solve the above-mentioned problems.

It is another objective of the present invention to provide an improved STI method having an ISSG film as an interface reinforcement layer so as to protect the STI edge from acid penetration.

According to one aspect of the present invention, a preferred embodiment of the present invention comprises the following steps: 1) providing a substrate having a top surface; 2) forming a trench-patterned mask layer on the top surface exposing an unmasked trench region of the substrate, the mask layer comprising a pad oxide layer and a silicon nitride layer formed on the pad oxide layer; 3) etching the unmasked region of the substrate to form a trench in the substrate; 4) simultaneously oxidizing the silicon nitride layer and the substrate of the trench to form an in-situ steam growth (ISSG) film; 5) depositing a dielectric layer that fills the trench and covers the mask layer; 6) planarizing the dielectric layer to expose the silicon nitride layer; and 7) stripping the silicon nitride.

It is advantageous to use the present invention since the ISSG film reinforces the interface between the dielectric layer and the substrate, to prevent acid penetration and acid-corroded seams forming during the acid solution dipping process.

These and other objectives and advantages of the present invention will no doubt become obvious to those of ordinary skilled in the art after reading the following detailed description of the preferred embodiment that is illustrated in the various figures and drawings.

### BRIEF DESCRIPTION OF DRAWINGS

FIG. 1 to FIG. 7 are schematic diagrams showing STI processes according to the prior art; and

FIG. 8 to FIG. 14 are schematic diagrams showing STI processes according to the present invention.

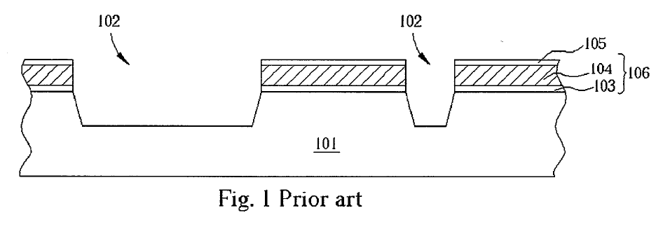

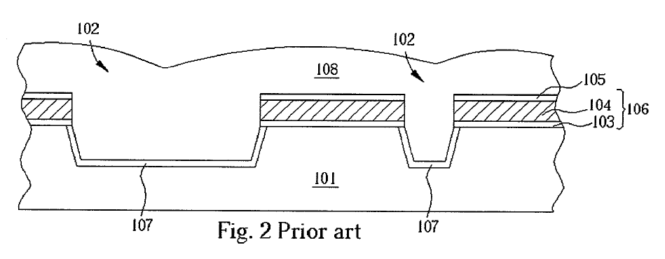

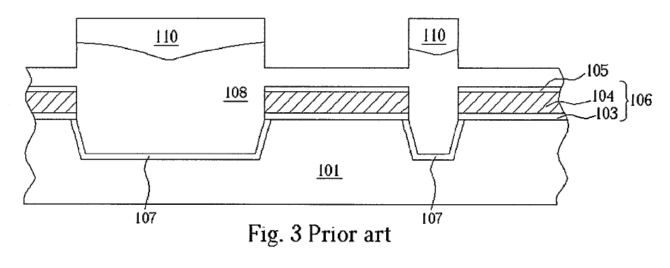

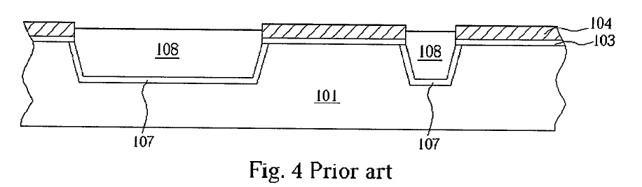

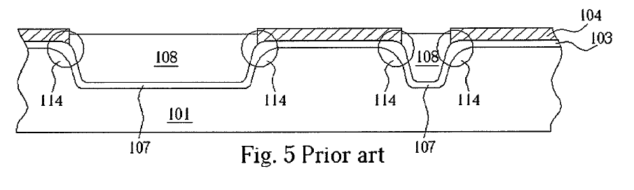

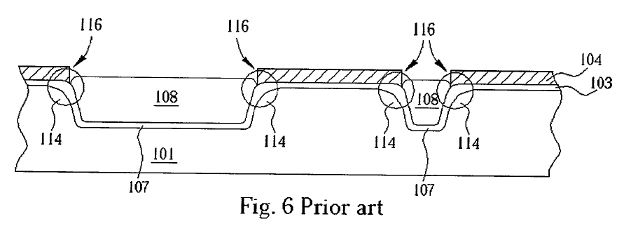

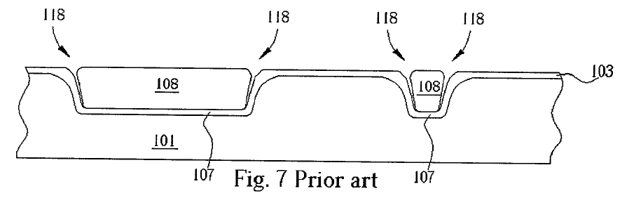

### DETAILED DESCRIPTION

The seamless STI with a unique ISSG film formed according to the preferred embodiment of the present invention is now described in detail.

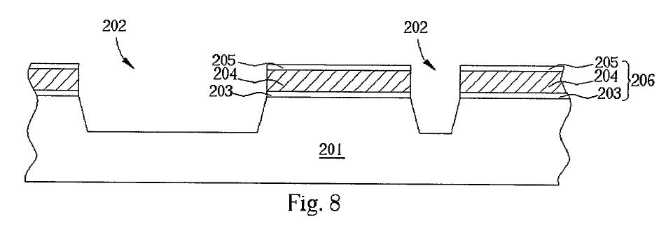

Please refer to FIG. 8 to FIG. 14 of schematic diagrams showing a seamless STI process according to the present invention. As shown in FIG. 8, a silicon substrate 201 is first provided. In the preferred embodiment of the present invention, the silicon substrate 201 is a P-type single crystal silicon substrate with a <100> crystalline orientation. Alternatively, the semiconductor substrate may be a silicon-on-insulator (SOI) substrate, an epitaxy silicon substrate, or any other silicon substrate of various lattice structures. A pad oxide layer 203 having a thickness of about 100 to 300 angstroms is formed on the surface of the silicon substrate 201 by using a thermal oxidization process at a temperature of 900° C. in an oxygen/hydrogen environment. A preferred thickness of the pad oxide layer 203 is about 200 angstroms.

A chemical vapor deposition process such as low-pressure chemical vapor deposition (LPCVD) is then performed to deposit a silicon nitride layer 204, 1800 to 2000 angstroms thick, over the pad oxide layer 203. The silicon nitride layer 204 is formed in a SiH2Cl2/NH3 system, at a temperature of about 750° C., and at a pressure of about 0.3 Torr. A dielectric anti-reflection coating (DARC) layer 205 is optionally coated over the silicon nitride layer 204. The DARC layer 205 has a thickness of about 500 angstroms. A preferred anti-reflection material is silicon oxynitride (SiON). The pad oxide layer 203, silicon nitride layer 204 and the DARC layer 205 form a stacked mask 206 used to define an STI region in the subsequent steps.

Still referring to FIG. 8, a lithographic process and an etching process are performed to etch a trench region 202 in the silicon substrate 201. The formation of the trench region 202 comprises the following steps: 1) exposing the trench region 202 of the silicon substrate 201 by trench-patterning the stacked mask 206; and 2) reactive ion etching the exposed trench region 202 of the silicon substrate 201 to form the trench region 202. The remaining thickness of the silicon nitride layer 204 after the formation of the trench region 202 is about 1700 angstroms.

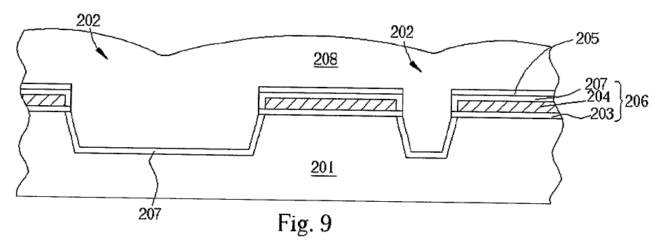

As shown in FIG. 9, an oxidation process in an atmosphere abundant in oxygen radicals and hydroxyl radicals is subsequently employed to form an in-situ steam generation or in-situ steam growth (ISSG) film 207 on the surface of the silicon nitride layer 204 and on the interior silicon surface of the trench region 202. Preferably, the thickness of the ISSG film is from 150 to 300 angstroms, and more preferably 200 angstroms. In the preferred embodiment of the present invention, the oxidation process with oxygen and hydroxyl radicals utilizes an in-situ steam growth (ISSG) technique. A high-density plasma CVD (HDPCVD) process is thereafter performed to deposit an 8000 angstroms thick HDP oxide layer over the ISSG film and that fills the trench region 202.

The ISSG process is performed in a single wafer type RTP chamber, such as an RTP XEplus Centura chamber available from Applied Materials, having 15 to 20 parallel arrayed tungsten halogen lamps located inside the top to rapidly raise the temperature of the wafer to a required temperature. In the preferred embodiment of the present invention, the ISSG film 207 is formed in a H2/O2 system with a total gas flowrate (TGF) of about 10 SLM (standard liters per minute), and the H2 accounting for 2% of the TGF, with a preferred RTP chamber pressure below 20 Torr, more preferably 10.5 Torr. At the beginning of the in-situ steam growth process, the silicon substrate 201 is lamp-heated to a temperature of about 1000° C. to 1200° C., more preferably 1150° C., and is kept at this temperature for about 20 to 25 seconds. Under the unique 20 Torr low pressure system, the ISSG process is performed in a desired mass transport controlled regime, which is sensitive to pressure variation.

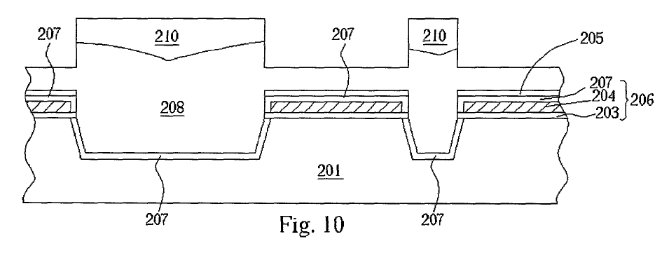

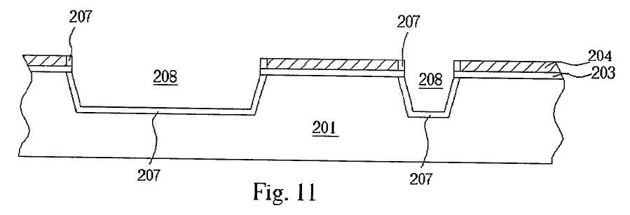

As shown in FIG. 10, a resistor layer (a reverse HDP oxide mask) 210 functions to shield the trench region 202, and an HDP oxide layer etching process is performed to etch the HDP oxide layer 208 outside the trench region 202. The purpose of the reverse HDP oxide mask and the HDP oxide layer etching process is to avoid dishing effects in the trench region 202 caused by a subsequent chemical mechanical polishing (CMP) process. The resistor layer 210 is thereafter stripped using a conventional dry ashing or wet cleaning process, as shown in FIG. 11, followed by a CMP process to planarize the HDP oxide layer 208. At the end point of the CMP process is detected on the silicon nitride layer 204. At this point, the remaining thickness of the silicon nitride layer 204 is approximately 1200 to 1300 angstroms. Notably, the present invention uses the ISSG film 207 to protect the interface between the HDP oxide layer 208 and the silicon nitride layer 204. The ISSG film 207 tightly adheres to both the HDP oxide layer 208 and the silicon nitride layer 204 so that acid penetration at the interface is prevented.

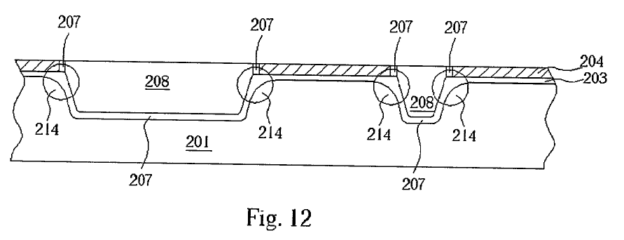

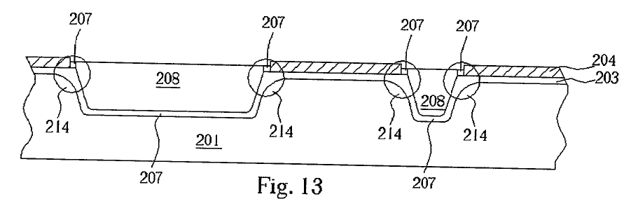

As shown in FIG. 12, an STI corner rounding process is then performed. The STI corner rounding process utilizes a wet oxidation method, which is performed at a high temperature of about 1075° C., to oxidize the silicon substrate 201 of a STI corner region 214. After that, it is advised to use an N2 annealing process at a temperature of about 1075° C. Then, as shown in FIG. 13, a silicon oxide dry etching process is performed to etch away residual silicon oxide remaining on the silicon nitride layer 204 and simultaneously etch away a predetermined thickness of the HDP oxide layer 208 within the trench region 202. In the preferred embodiment, the predetermined thickness of etched HDP oxide layer 208 is about several hundred angstroms. The dry etching process can further reduce the possibility of acid penetration.

Also, in other embodiments of the present invention, wet acid dipping processes may be used to wash away the residual silicon oxide left on the silicon nitride layer 204 and etch a predetermined thickness of the HDP oxide layer 208 due to the benefit created by the ISSG film 207 which protects the trench region 202 corner edge. The wet acid dipping processes may use 50:1 (v/v) diluted HF solution, 100:1 (v/v) diluted HF solution, or any other HF-containing acid solution.

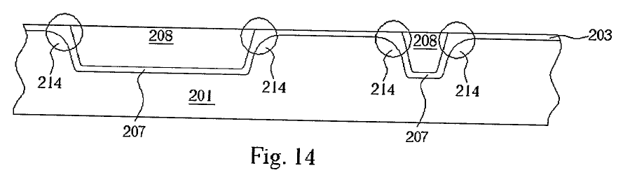

Finally, as shown in FIG. 14, a 160° C. phosphoric acid solution is used to strip the silicon nitride layer 204. Then, a 100:1 (v/v) diluted HF (DHF) solution is utilized to clean the surface of the substrate 201 again for a few minutes at room temperature. The present invention features the ISSG film 207 that is formed by the in-situ steam growth technique. The ISSG film functions as an interface reinforcement layer preventing the interface between the HDP oxide layer 208 and the silicon nitride layer 204 from penetration by acid, effectively choking the path of acid solution to the STI edges and preventing acid penetration.

In contrast to the prior art, the features of the present invention include: 1) the thermal liner used in the prior art method is now replaced with the ISSG film 207 that eliminates the acid-corroded seam defects caused by acid penetration at the weak HDP oxide-silicon nitride interfaces; 2) the ISSG film 207 taught in the present invention has a superior uniformity characteristic and more networked structure compared with the prior art thermally formed liner; 3) the ISSG film 207 is simultaneously formed on the silicon nitride layer 204 and the trench region 202; and 4) STI corner region is well protected because of the dense ISSG film 207.

Those skilled in the art will readily observe that numerous modification and alterations of the advice may be made while retaining the teachings of the invention. Accordingly, the above disclosure should be construed as limited only by the metes and bounds of the appended claims.

What is claimed is:

1. A method for improving the reliability of shallow trench isolation (STI), the method comprising:
providing a substrate having a top surface;
forming a trench-patterned mask layer on the top surface exposing an unmasked trench region of the substrate, the mask layer comprising a pad oxide layer, and a silicon nitride layer formed on the pad oxide layer;
etching the unmasked region of the substrate to form a trench in the substrate;
simultaneously oxidizing the silicon nitride layer and the substrate of the trench to form an in-situ steam growth (ISSG) film;
depositing a dielectric layer to fill the trench and cover the mask layer;
planarizing the dielectric layer to expose the silicon nitride layer; and
stripping the silicon nitride;
wherein the ISSG film reinforces an interface between the dielectric layer and the substrate to prevent acid penetration and acid-corroded seams being formed during the acid solution dipping process.

2. The method of claim 1 wherein the ISSG film is formed by an in-situ steam growth (ISSG) method.

3. The method of claim 1 wherein the ISSG film has a thickness between 50 and 250 angstroms.

4. The method of claim 1 wherein the dielectric layer is an HDP (high density plasma, HDP) oxide layer.

5. The method of claim 1 wherein before stripping the silicon nitride layer, the method further comprises performing a silicon oxide etching process to remove residual silicon oxide on the silicon nitride layer and simultaneously etch the dielectric layer of the trench.

6. The method of claim 1 wherein the acid solution dipping process uses DHF (diluted HF) solution.

7. The method of claim 1 wherein the silicon nitride layer is stripped by a 160° C. phosphoric acid solution.

8. The method of claim 1 wherein the substrate is a silicon substrate.
